(19) United States
(12) Patent Application Publication
(10) Pub. No.: US 2022/0333243 A1
(43) Pub. Date: Oct. 20, 2022

(54) METHOD FOR FORMING METAL NITRIDE THIN FILM

(71) Applicant: EGTM CO., LTD., Suwon-si, Gyeonggi-do (KR)

(72) Inventors: Geun Su LEE, Suwon-si , Gyeonggi-do (KR); Gil Jae PARK, Busan (KR); Jong Tae HONG, Suwon-si, Gyeonggi-do (KR); Cheol Hee SHIN, Suwon-si, Gyeonggi-do (KR)

(73) Assignee: EGTM CO., LTD., Suwon-si, Gyeonggi-do (KR)

(21) Appl. No.: 17/640,330

(22) PCT Filed: Jul. 24, 2020
(86) PCT No.: PCT/KR2020/009806

§ 371 Date: Mar. 3, 2022

(30) Foreign Application Priority Data
Sep. 3, 2019 (KR) 10-2019-0108609

(51) Int. Cl. C23C 16/455; C23C 16/34

(52) U.S. Cl. CPC C23C 16/45553; C23C 16/34; C23C 16/45527

(57) ABSTRACT

Disclosed is a method of a method of depositing metal nitride thin films, the method comprising: a deposition step of supplying a metal precursor, so that the metal precursor is deposited selectively on a surface of the substrate; a halogen treatment step of supplying a halogen gas to the substrate to form a metal halogen compound on a surface of the substrate; and a nitridation step of supplying a nitrogen source to the substrate to react with the metal halogen compound to form a metal nitride.

### TECHNICAL FIELD

The present invention relates to a method for forming a metal nitride thin film, and more particularly, to a method for forming a metal nitride thin film using a halogen gas.

### BACKGROUND ART

Metal nitride films such as niobium nitride (NbNx, where x is about 1) have been widely used in various technical fields. Traditionally these nitrides have been applied as hard and decorative coatings, but over the past few decades they have been increasingly used as diffusion barriers and adhesion/glue layers in microelectronic devices [AppliedSurface Science 120 (1997) 199-212].

For example, NbCl5 has been investigated as a niobium source for atomic layer epitaxial growth of NbN, but this method required Zn as a reducing agent [Applied Surface Science 82/83 (1994) 468-474]. NbNx films were also deposited by atomic layer deposition using NbCl5 and NH3 [Thin Solid Films 491(2005) 235-241]. The film deposited at 500° C. showed a strong temperature dependence of chlorine content as if almost chlorine free, but when the deposition temperature was as low as 250° C., the chlorine content was 8%. The high melting point of NbCl5 also makes it difficult to use the precursor in the deposition process.

Gust et al. discloses the synthesis, structure and characterization of niobium bearing pyrazolato ligand and tantalum imido complexes, and their potential use for growth of tantalum nitride films by CVD. Elorriaga et al. discloses asymmetric niobium guanidinate as an intermediate in the catalytic guanylation of amines (Dalton Transactions, 2013, Vol. 42, Issue 23 pp. 8223-8230).

Tomson et al. discloses the synthesis and reactivity of cationic Nb and Ta monomethyl complex [(BDI)MeM(NtBu)][X](BDI=2, 6-iPr2C6H3-NC(Me)CH—C(Me)-N(2, 6-iPr2C6H3); X=MeB(C6F5)3 or B(C6F5)4)(Dalton Transactions 2011 Vol. 40, Issue 30, pp. 7718-7729).

DE102006037955 (Starck) discloses tantalum- and niobium- compounds having the formula R4R5R6M(R1NNR2R3)2 (wherein M is Ta or Nb; R1-R3=C1-12 alkyl, C5-12 cycloalkyl, C6-10 aryl, alkenyl, C1-4 triorganosilyl R4-R6=halo, (cyclo)alkoxy, aryloxy, siloxy, BH4, allyl, indenyl, benzyl, cyclopentadienyl, CH2SiMe3, silylamido, amido or imino-).

Maestre et al. discloses the reaction of a cyclopentadienyl-silyl-amido titanium compound and the Group 5 metal monocyclopentadienyl complex to form NbCp(NH(CH2)2-NH2) C13 and NbCpCl2(N—(CH2)2-N).

There is still a need to develop Group V-containing precursor molecules suitable for vapor phase film deposition with thickness and composition control at high temperatures, which is a novel liquid or low melting point (<50° C. at standard pressure) and has high thermal stability. In addition, although a physical vapor deposition method such as sputtering is used to form fine metal wiring, step coverage is poor in this physical vapor deposition method.

Chemical vapor deposition (CVD) has been developed as a thin film deposition technology with uniform deposition characteristics and step coverage according to the recent trend of super integration and thinning of semiconductor devices. However, in the case of the chemical vapor deposition method, since all materials necessary for thin film formation are simultaneously supplied into the process chamber, it is difficult to form a film having the desired composition ratio, and the process is conducted at high temperature, thereby deteriorating the electrical characteristics of the device or lowering the storage capacity. In order to solve this problem, an atomic layer deposition (ALD) method in which a process gas is independently supplied rather than continuously supplied has been developed.

### DISCLOSURE OF THE INVENTION

### Technical Problem

The present invention provides to a method capable of effectively forming a metal nitride thin film.

Further another object of the present invention will become evident with reference to following detailed descriptions and drawings.

### Technical Solution

Disclosed is a method of a method of depositing metal nitride thin films, the method comprising: a deposition step of supplying a metal precursor, so that the metal precursor is deposited selectively on a surface of the substrate; a halogen treatment step of supplying a halogen gas to the substrate to form a metal halogen compound on a surface of the substrate; and a nitridation step of supplying a nitrogen source to the substrate to react with the metal halogen compound to form a metal nitride.

The metal nitride may be MₐN_{b} (M is one of V, Nb, Ta, and W, 1≤a≤4, 1≤b≤5).

The metal precursor may be at least one of MXₙ(NR₁R₂)₅₋₂(1≤n≤4), MX(NR₁R₂)₂NR₃, MX₂(NR₁R₂)NR₃, and M(NR₁R₂)₂(NR₃)R₄.

In MXₙ(NR₁R₂)₅₋ₙ, M is one of V, Nb, Ta, and W, X is one of Group 17 including F, Cl, Br, and I, R₁ and R₂ are each independently one of linear/branched/cyclic hydrocarbons having 1 to 10 carbon atoms, and may be the same as or different from each other.

MX(NR₁R₂)₂NR₃ may be represented by the following Chemical Formula 1:

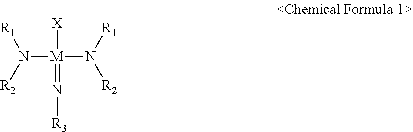

in MX(NR₁R₂)₂NR₃,

M is one of V, Nb, Ta, and W,

X is one of Group 17 including F, Cl, Br, and I,

R₁, R₂ and R₃ are each independently one of linear/branched/cyclic hydrocarbons having 1 to 10 carbon atoms and are the same as or different from each other.

MX₂(NR₁R₂)NR₃ may be represented by the following Chemical Formula 2:

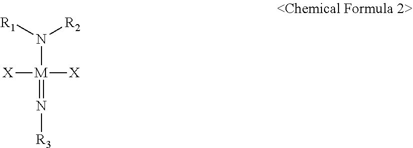

in MX₂ (NR₁R₂)NR₃,

M is one of V, Nb, Ta, and W,

X is one of Group 17 including F, Cl, Br, and I,

R₁, R₂ and R₃ are each independently one of linear/branched/cyclic hydrocarbons having 1 to 10 carbon atoms and are the same as or different from each other.

M(NR₁R₂)₂(NR₃)R₄ may be represented by the following Chemical Formula 3:

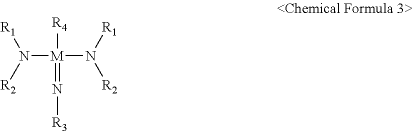

in M (NR₁R₂) ₂ (NR₃) R₄,

M is one of V, Nb, Ta, and W,

X is one of Group 17 including F, Cl, Br, and I,

R₁, R₂, R₃ and R₄ are each independently one of a linear/branched/cyclic hydrocarbons having 1 to 10 carbon atoms and are the same as or different from each other.

The metal precursor may be supplied with a carrier gas, the carrier gas is at least one of an inert gas containing nitrogen (N₂), argon (Ar), and helium (He).

The halogen gas may be at least one of X₂ and HX.

The nitrogen source may be at least one of NH₃, NHR₂ (R is at least one of a C₁-C₅ linear, branched, aromatic alkyl group), NH₂R (R is at least one of a C₁-C₅ linear, branched, or aromatic alkyl group), NR₃ (R is C₁-C₅ linear, branched, aromatic alkyl group), hydrazine (H₄N₂), R-hydrazine (R is at least one of C₁-C₅ linear, branched, aromatic alkyl group), N₂ plasma, and NH₃ plasma.

The deposition step, the halogen treatment step, and the nitridation step may be each performed at 250 to 600° C.

The deposition step, the halogen treatment step, and the nitridation step may form one cycle, the cycle is repeated.

### Advantageous Effects

According to an embodiment of the present invention, it can be confirmed that the metal precursors are suitable for depositing a metal nitride (eg, a niobium thin film), and the metal precursors have high thermal stability in which the properties are not deteriorated even with continuous heating. By having a high vapor pressure, it can be confirmed that the metal precursors are usefully applied to the semiconductor manufacturing process of depositing a metal nitride thin film using Metal Organic Chemical Vapor Deposition (MOCVD) and Atomic Layer Deposition (ALD).

In addition, it can be seen that the method of forming a metal nitride thin film using metal precursors can be advantageously applied to the formation of a metal nitride thin film free of carbon and halogen impurities.

### DESCRIPTION OF DRAWINGS

FIG. 1 is a flowchart schematically demonstrating a method of forming a metal nitride thin film according to an embodiment of the present invention.

FIGS. 2 and 3 show schematically a process of forming a metal nitride thin film according to an embodiment of the present invention.

### BEST MODE

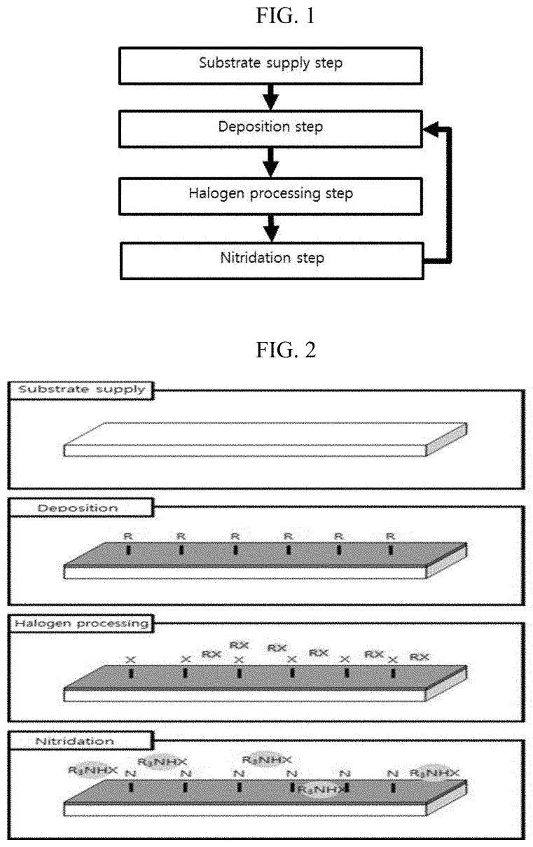

Hereinafter, preferred embodiments of the present invention will be described in more detail with reference to FIGS. 1 to 3. The present invention may be embodied in different forms and should not be constructed as limited to the embodiments set forth herein. Rather, the embodiments are provided to explain the present invention more completely to those skilled in the art to which the present invention pertains. Therefore, the dimensions of each component shown in the figures are exaggerated for clarity of description.

First, since the previously used precursor NbCl5 is a solid, clogging of the piping in the deposition equipment occurs, and it is difficult to sublimate into a gas and transfer a certain amount to the deposition chamber. In addition, other organometallic precursors have a problem in that impurities affect the film quality because of their high carbon content.

The method of forming a metal (V) nitride thin film to be described below is a method of forming a thin film on the surface of a substrate through atomic layer deposition (ALD) (or metal organic chemical vapor deposition). And, the following general formulas show a reaction formula for forming a thin film free of impurities of carbon and halogen even when a liquid precursor is used, comparing to conventional solid precursors.

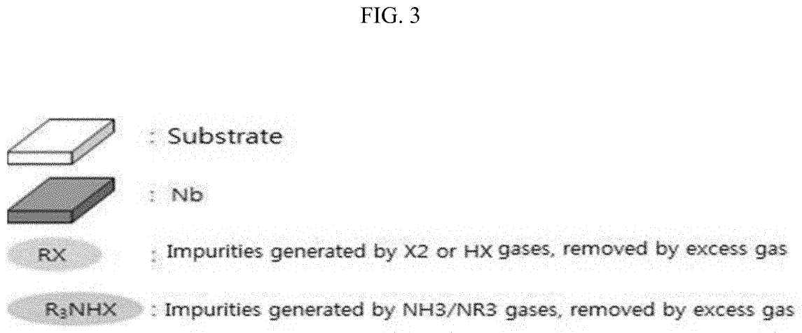

FIG. 1 is a flowchart schematically demonstrating a method of forming a metal nitride thin film according to an embodiment of the present invention. FIGS. 2 and 3 show schematically a process of forming a metal nitride thin film according to an embodiment of the present invention.

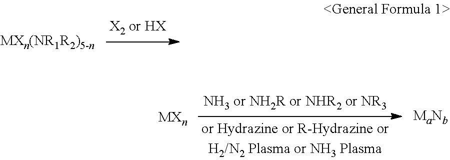

M=V, Nb, Ta, and W(the oxidation state of M is (I˜V) or a mixed state),

X=one of Group 17 including F, Cl, Br, and I,

R₁ and R₂ are each independently one of linear/branched/cyclic alkyl groups having 1 to 10 carbon atoms and are the same as or different from each other.

1≤n≤4

1≤a≤4

1≤b≤5

The MXₙ(NR₁R₂)₅₋ₙ is a metal (V) precursor for forming a metal nitride thin film. Shown in FIGS. 1 to 3 (when M=Nb), a substrate is supplied into the chamber (‘substrate supply step’), and a metal precursor is supplied to the substrate in the chamber and selectively deposited on the surface of the substrate (‘deposition step’). The metal precursor may be supplied into the chamber through a liquid delivery system, and at this time, it may be vaporized at an appropriate temperature and delivered in a uniform gaseous form.

In addition, various methods including bubbling method, vapor phase mass flow controller (MFC), direct liquid injection (DLI), or liquid transfer method in which a precursor compound is dissolved in an organic solvent and transferred may be applied. As a carrier gas for supplying the metal precursor, one or more mixtures of nitrogen (N₂), argon (Ar), helium (He), or hydrogen (H₂) may be used.

Thereafter, a halogen gas (X₂ or HX) is supplied to the substrate in the chamber, and the halogen gas can form a metal halogen compound on the surface of the substrate and remove impurities in the form of R-Cl (‘halogen processing steps’).

Thereafter, a nitrogen source is supplied to the substrate to remove reaction byproducts and unreacted materials, and at the same time, react with a metal halogen compound to form a metal nitride (‘nitridation step’). Nitrogen source is at least one of NH₃, NHR₂ (R is at least one of a C₁-C₅ linear, branched, aromatic alkyl group), NH₂R (R is at least one of a C₁-C₅ linear, branched, or aromatic alkyl group), NR₃ (R is C₁-C₅ linear, branched, aromatic alkyl group), hydrazine (H₄N₂), R-hydrazine (R is at least one of C₁-C₅ linear, branched, aromatic alkyl group), H₂/N₂ plasma, and NH₃ plasma, impurities may be removed with (R3N)-HCl salt (R=linear, branched, cyclic alkyl group having 1 to 5 carbon atoms).

Meanwhile, the deposition step, the halogen treatment step, and the nitridation step may be performed at 250 to 600° C., respectively. In addition, the deposition step, the halogen treatment step, and the nitriding step form one cycle, and the cycle may be repeated several times.

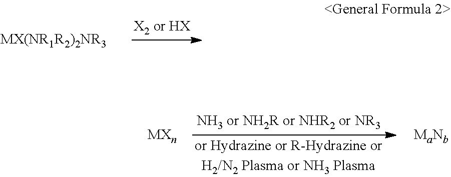

M=V, Nb, Ta, and W(the oxidation state of M is (I˜V) or a mixed state),

X=one of Group 17 including F, Cl, Br, and I,

R₁, R₂, and R₃ are each independently one of linear/branched/cyclic alkyl groups having 1 to 10 carbon atoms and are the same as or different from each other.

1≤n≤4

1≤a≤4

1≤b≤5

MX(NR₁R₂)₂NR₃ is a metal (V) precursor for forming a metal nitride thin film, may be represented by the following Chemical Formula 1:

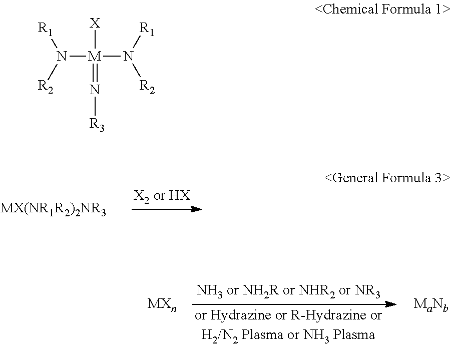

M=V, Nb, Ta, and W(the oxidation state of M is (I˜V) or a mixed state),

X=one of Group 17 including F, Cl, Br, and I,

R₁, R₂, and R₃ are each independently one of linear/branched/cyclic alkyl groups having 1 to 10 carbon atoms and are the same as or different from each other.

1≤n≤4

1≤a≤4

1≤b≤5

MX₂(NR₁R₂)NR₃ is a metal (V) precursor for forming a metal nitride thin film, may be represented by the following

Chemical Formula 2:

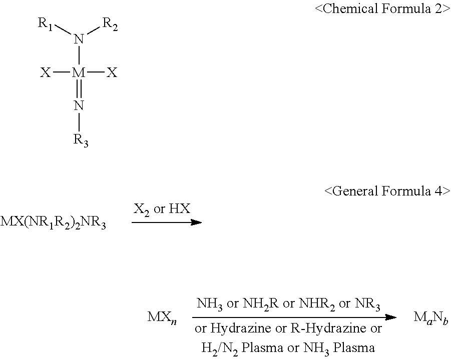

M=V, Nb, Ta, and W (the oxidation state of M is (I˜V) or a mixed state),

X=one of Group 17 including F, Cl, Br, and I,

R₁, R₂, R₃, and R₄ are each independently one of alkyl groups having 1 to 10 carbon atoms and are the same as or different from each other.

1≤n≤4

1≤a≤4

1≤b≤5

M(NR₁R₂)₂(NR₃)R₄ is a metal (V) precursor for forming a metal nitride thin film, may be represented by the following Chemical Formula 3:

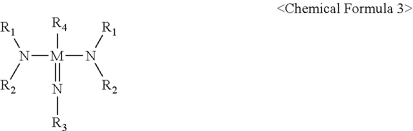

The present invention has been explained in detail with reference to embodiments, but other embodiments may be included. Accordingly, the technical idea and scope described in the claims below are not limited to the embodiments.

### INDUSTRIAL APPLICABILITY

The present invention may be applicable to a various apparatus for manufacturing semiconductor or a various method for manufacturing semiconductor.

1. A method for forming metal nitride thin film, the method comprising:
a deposition step of supplying a metal precursor, so that the metal precursor is deposited selectively on a surface of the substrate;
a halogen treatment step of supplying a halogen gas to the substrate to form a metal halogen compound on a surface of the substrate; and
a nitridation step of supplying a nitrogen source to the substrate to react with the metal halogen compound to form a metal nitride.

2. The method of claim 1, wherein the metal nitride is MₐN_{b} (M is one of V, Nb, Ta, and W, 1≤a≤4, 1≤b≤5).

3. The method of claim 1, wherein the metal precursor is at least one of MXₙ(NR₁R₂)₅₋ₙ(1≤n≤4), MX(NR₁R₂)₂NR₃, MX₂(NR₁R₂)NR₃, and M(NR₁R₂)₂(NR₃)R₄.

4. The method of claim 3, wherein in MXₙ(NR₁R₂)₅₋ₙ,
M is one of V, Nb, Ta, and W,
X is one of Group 17 including F, Cl, Br, and I,
R₁ and R₂ are each independently one of linear/branched/cyclic hydrocarbons having 1 to 10 carbon atoms, and are the same as or different from each other.

5. The method of claim 3, wherein MX(NR₁R₂)₂NR₃ is represented by the following Chemical Formula 1: 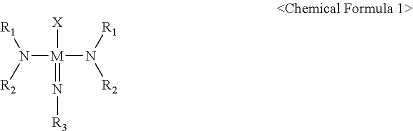
in MX(NR₁R₂)₂NR₃,
M is one of V, Nb, Ta, and W,
X is one of Group 17 including F, Cl, Br, and I,
R₁, R₂ and R₃ are each independently one of linear/branched/cyclic hydrocarbons having 1 to 10 carbon atoms and are the same as or different from each other.

6. The method of claim 3, wherein MX₂(NR₁R₂)NR₃ is represented by the following Chemical Formula 2: 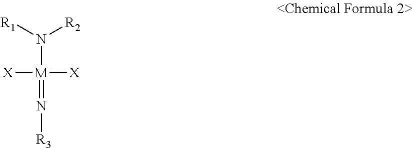
in MX₂(NR₁R₂)NR₃,
M is one of V, Nb, Ta, and W,
X is one of Group 17 including F, Cl, Br, and I,
R₁, R₂ and R₃ are each independently one of linear/branched/cyclic hydrocarbons having 1 to 10 carbon atoms and are the same as or different from each other.

7. The method of claim 3, wherein M(NR₁R₂)₂(NR₃)R₄ is represented by the following Chemical Formula 3: 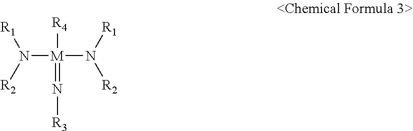
in M(NR₁R₂)₂(NR₃)R₄,
M is one of V, Nb, Ta, and W,
X is one of Group 17 including F, Cl, Br, and I,
R₁, R₂, R₃ and R₄ are each independently one of linear/branched/cyclic hydrocarbons having 1 to 10 carbon atoms and are the same as or different from each other.

8. The method according to claim 1, wherein the metal precursor is supplied with a carrier gas, the carrier gas is at least one of an inert gas containing nitrogen (N₂), argon (Ar), and helium (He).

9. The method according to claim 1, wherein the halogen gas is at least one of X₂ and HX.

10. The method according to claim 1, wherein the nitrogen source is at least one of NH₃, NHR₂ (R is at least one of a C₁-C₅ linear, branched, aromatic alkyl group), NH₂R (R is at least one of a C₁-C₅ linear, branched, or aromatic alkyl group), NR₃ (R is C₁-C₂ linear, branched, aromatic alkyl group), hydrazine (H₄N₂), R-hydrazine (R is at least one of C₁-C₅ linear, branched, aromatic alkyl group), N₂ plasma, and NH₃ plasma.

11. The method according to claim 1, wherein the deposition step, the halogen treatment step, and the nitridation step are each performed at 250 to 600° C.

12. The method according to claim 1, wherein the deposition step, the halogen treatment step, and the nitridation step form one cycle, the cycle is repeated.

13. The method according to claim 2, wherein the metal precursor is supplied with a carrier gas, the carrier gas is at least one of an inert gas containing nitrogen (N₂), argon (Ar), and helium (He).

14. The method according to claim 3, wherein the metal precursor is supplied with a carrier gas, the carrier gas is at least one of an inert gas containing nitrogen (N₂), argon (Ar), and helium (He).

15. The method according to claim 2, wherein the halogen gas is at least one of X₂ and HX.

16. The method according to claim 3, wherein the halogen gas is at least one of X₂ and HX.

17. The method according to claim 2, wherein the nitrogen source is at least one of NH₃, NHR₂ (R is at least one of a C₁-C₅ linear, branched, aromatic alkyl group), NH₂R (R is at least one of a C₁-C₅ linear, branched, or aromatic alkyl group), NR₃ (R is C₁-C₅ linear, branched, aromatic alkyl group), hydrazine (H₄N₂), R-hydrazine (R is at least one of C₁-C₅ linear, branched, aromatic alkyl group), N₂ plasma, and NH₃ plasma.

18. The method according to claim 3, wherein the nitrogen source is at least one of NH₃, NHR₂ (R is at least one of a C₁-C₅ linear, branched, aromatic alkyl group), NH₂R (R is at least one of a C₁-C₅ linear, branched, or aromatic alkyl group), NR₃ (R is C₁-C₅ linear, branched, aromatic alkyl group), hydrazine (H₄N₂), R-hydrazine (R is at least one of C₁-C₅ linear, branched, aromatic alkyl group), N₂ plasma, and NH₃ plasma.

19. The method according to claim 2, wherein the deposition step, the halogen treatment step, and the nitridation step are each performed at 250 to 600° C.

20. The method according to claim 2, wherein the deposition step, the halogen treatment step, and the nitridation step form one cycle, the cycle is repeated.
